(19) United States
(12) Patent Application Publication
(10) Pub. No.: US 2013/0276882 A1
(43) Pub. Date: Oct. 24, 2013

(54) METHOD FOR FORMING CONDUCTIVE STRUCTURES IN A SOLAR CELL

(71) Applicants: Mark Buchanan, Oslo (NO); Matti Knaapila, Drammen (NO); Sean Erik Foss, Skedsmokorset (NO); Geir Helgesen, Finstadjordet (NO)

(72) Inventors: Mark Buchanan, Oslo (NO); Matti Knaapila, Drammen (NO); Sean Erik Foss, Skedsmokorset (NO); Geir Helgesen, Finstadjordet (NO)

(73) Assignee: CONDALIGN AS, Kjeller (NO)

(21) Appl. No.: 13/996,910

(22) PCT Filed: Dec. 21, 2011
(86) PCT No.: PCT/EP11/73592

§ 371 Date: Jun. 21, 2013

(30) Foreign Application Priority Data
Dec. 21, 2010 (NO) 20101784

(51) Int. Cl. H01L 31/0224

(52) U.S. Cl. CPC H01L 31/022433
USPC 136/256; 438/98

(57) ABSTRACT

A method for forming a solar cell and a solar cell having a top electrode with a finger pattern. The finger pattern is formed of a structure of aligned particles that is formed by applying a thin film comprising a fluid matrix with conductive particles on to the solar cell surface, aligning the conductive particles into electrically conductive wires by applying an electric field over the thin film and curing the matrix.

### BACKGROUND

Solar cells require conductive tracks on the surface of the cells to harvest and transport electrical current produced in the photovoltaic process. The conductive tracks are typically made from silver or silver alloys applied to the surface using screen printing or ink jet processes.

The electrons generated by light are moving first through the solar cell body, usually made of silicon, and then transported via conductive tracks. As the conductivity of the tracks is much higher than that of solar cell body, the overall resistance (the series resistance) could be greatly lowered if the electrons could move shorter distance, that is to say if the electrodes were closer to each others.

In a conventional solar cell configuration the tracks are located on the front side of the cell, blocking a part of the solar cell surface and thus decreasing the amount of incident light reaching the solar cell body whereby the efficiency of the cell is decreased.

The width of the tracks (0.5 mm) is limited by the contemporary screen printing process technology that does not allow formation of thinner electrodes, which could allow a denser array to be formed and yet not block more of the solar cell area.

A method of forming a conductive contact pattern on a surface of a solar cell is described in WO2010123976, where a conductive layer is formed on a surface of a solar cell and ablating the majority of the thin conductive layer using a laser beam to form thin structures (<10 microns) of fingers and bus bars. This method is however complicated and expensive, in respect of investments, production time and waste material generated.

### DESCRIPTION OF THE INVENTION

The present invention concerns a method of forming solar cell having a top electrode comprising a finger pattern, where at least part of the finger pattern is formed of aligned assemblies of conductive particles.

The method comprises the following steps:
applying a thin film comprising a fluid matrix with typically micrometer-sized conductive particles on to the solar cell surface
aligning the conductive particles by applying an electric field over the thin film
curing the matrix

The matrix should preferably be transparent in order not to block light from reaching the solar cell surface. A main part of the matrix could be removed after the curing. The conductive particles left on the surface can be aligned as lines or form dendrite structures onto pre-formed finger lines or aligned particle lines.

The alignment of the particles is achieved by applying an electric field over the thin film, the field will cause the conductive particles to align along the field lines.

The thin structures formed by the aligned conductive particles allow the formation of a top electrode having short inter-electrode distances which result in low contact resistance without need to increase the lateral electrode area. The short distances between parts of the electrode in the structure of aligned conductive particles reduce recombination of the generated electrons in the solar cell. The efficiency of the solar cell can thereby be improved.

The relation between resistance R and the electrode spacing (finger distance) S is given as

$$R = {\int }_{0}^{S / 2} \frac{ρ}{l} d y = \frac{ρ}{2 l} S , \qquad ( 1 )$$

where p is the sheet resistivity and/the distance along the electrode (finger). The relation of these parameters and the integration of Equation 1 are illustrated in FIG. 1 which describes the relation between resistance R, the length of solar cell electrode l and the electrode-electrode distance S. a:s illustrate solar cell top electrodes on top of the solar cell body b.

From the Equation 1 it can be seen that since the current I is proportional to the distance S between electrodes, the power loss I²R scales as S³.

Alternatively, the electrode area can be reduced which increases the effective area of the cell and thus relative increase of solar cell efficiency is achieved without increasing the series resistance.

The small conductive particles can be particles of a metal or metal alloy, like Ag or alloys of Ag, Cu, Au, Fe or Ti or alloys thereof or oxides, like Fe₃O₄ or TiO₂, or carbon particles, like carbon nanotubes, carbon nanocones, graphitic particles, graphene particles or carbon black particles. The sizes of the particles are in the range of 0.1-100 μm or 0.1-10 μm or 0.3-3 μm

The structure of aligned conductive particles can form a finger pattern of finger lines, where the finger lines, compared to the typical commercial solar cell top electrodes, can be closer to each other in order to reduce the series resistance in the cell. The finger lines could also be provided with a dendrite structure of aligned particles, making the distance between parts of the electrode even shorter. A dendrite structure can also be formed onto pre-formed conventional finger lines, in order to increase the reach of the electrode.

The top electrode comprising the structure of aligned conductive particles on the surface of the solar cell gives several advantages:
Reduced series resistance in the cell
Reduced amount of silver, if silver is used for the finger pattern
Silver can be replaced with less conductive but less expensive particles such as carbon nano materials
Controlled structures can be achieved by using electric field
Very thin wires of aligned particles can be formed thus reducing the area of electrodes blocking the incoming light.

In summary the present invention is a method for forming a solar cell having a top electrode comprising a finger pattern, where at least part of the finger pattern is formed of a structure of aligned particles, said structure being formed by
applying a thin film comprising a fluid matrix with conductive particles on to the solar cell surface;
aligning the conductive particles into electrically conductive wires by applying an electric field over the thin film
curing the matrix

The conductive particles can be of a metal or metal alloy, like Ag or alloys of Ag, Cu, Au, Fe or Ti or alloys thereof or oxides, like Fe₃O₄ or TiO₂

or carbon particles, like carbon nanotubes, carbon nanocones, graphitic particles, graphene particles or carbon black particles.

The aligned conductive particles form thin wires having a width of less than 50 microns or less than 10 microns. These wires can also be finger lines.

A second thin film can be applied to the surface and the aligning of the conductive particles of the second thin film made so that a dendrite structure is formed on the finger lines.

The thin film can be applied to the solar cell surface after finger lines have been printed onto the surface and the aligning of the conductive particles is made so that a dendrite structure is formed on the finger lines.

The thin film can be prepared separately and transferred onto the solar cell after alignment of particles.

As explained in the above, the invention relates to a method for forming a solar cell having a top electrode comprising a finger pattern, wherein at least part of the finger pattern is formed of a structure of aligned particles, said structure being formed by
applying a thin film comprising a fluid matrix with conductive particles on to the solar cell surface;
aligning the conductive particles into electrically conductive wires by applying an electric field over the thin film
curing the matrix

Advantageously, the conductive particles are particles of a metal or metal alloy, like Ag or alloys of Ag, Cu, Au, Fe or Ti or alloys thereof or oxides, like Fe₃O₄ or TiO₂

Alternatively, the conductive particles are particles or carbon particles, like carbon nanotubes, carbon nanocones, graphitic particles, graphene particles or carbon black particles.

Preferably, the aligned conductive particles form thin wires having a width of less than 50 microns or less than 10 microns.

Advantageously, the aligned conductive particles form finger lines.

Preferably, a second thin film may be applied to the surface and the aligning of the conductive particles of the second thin film is made so that a dendrite structure is formed on the finger lines.

Alternatively, the thin film is applied to the solar cell surface after finger lines have been printed onto the surface and the aligning of the conductive particles is made so that a dendrite structure is formed on the finger lines.

Advantageously, the thin film may be prepared separately and transferred onto the solar cell after alignment of particles.

In a second aspect, the invention relates to a solar cell manufactured in accordance with the above. Preferably, the solar cell is a silicon solar cell manufactured in accordance with the above.

### LIST OF DRAWINGS

FIG. 1 shows the top view of a solar cell with finger-like top electrodes and illustrates the meaning of the symbols of equation 1.

FIG. 2. shows the schematics of the idea of dendritic electrodes on the solar cell.

FIG. 3 illustrates dendritic structures maximizing the contact area between conductive item and matrix.

FIG. 4. shows optical micrograph of Fe₃O₄ dendrimers.

FIG. 5 shows optical micrograph of silver dendrimers.

FIG. 6. shows optical micrograph of the silver particles on the silicon solar cell.

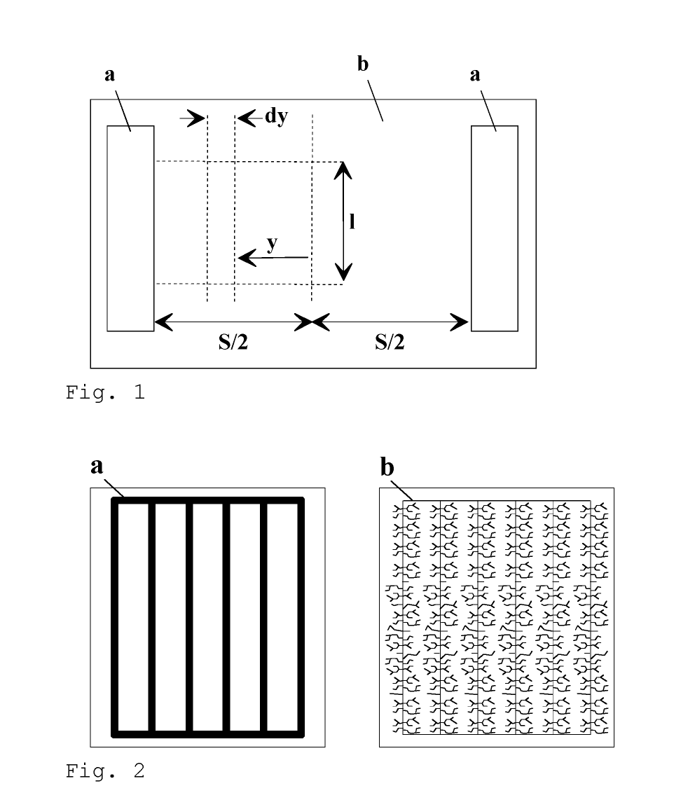

### EXAMPLES

In all embodiments, the method comprises the mixing of infusible conductive particles and fluid matrix that contains at least polymer, the electric field alignment of conductive particles mixed in this fluid and the control of the viscosity of this mixture by curing it. This procedure can be done over the solar cell to replace conventional top electrodes by thin wires of aligned assemblies of conductive particles. These situations are illustrated in FIG. 2 that shows the schematics of the idea of dendritic electrodes on the solar cell: Conventional surface electrodes with higher mutual distance, a, and dendritic surface electrodes with smaller relative distance, b. The electrode area is the same in both cases.

The resultant aligned material retains anisotropic properties such as directional electrical conductivity. In this way, aligned conductive microstructures of originally infusible particles which do not allow alignment as such are formed.

The invention will be further described by the following examples. These are intended to embody the invention but not to limit its scope.

### Example 1

This example concerns the use of electric field alignment when preparing electrodes with very large contact area dendrimer surface.

This example concerns the preparation of a mixture of conductive particles and polymer matrix that in this example is a thermally cured polymer adhesive;

This example concerns moreover the preparation of the same mixture when the particle load is low, for example 10 times less than the observed percolation threshold, the limit where the isotropic non-aligned mixture is not conductive; as well as the alignment of this mixture using electric field so that the aligned particles form conductive paths resulting in a conductive material, whose conductivity is directional. The example, moreover, shows change of the viscosity of so obtained material, by curing, so that the alignment and directional conductivity obtained in the alignment step is maintained.

The employed conductive particles were carbon nanocones from n-Tec AS (Norway).

Thermoset, photocurable thermoset, and thermoplastic polymers were used.

The thermoset polymer was a two component low viscosity adhesive formed by combining Araldite® AY 105-1 (Huntsman Advanced Materials GmbH) with low viscosity epoxy resin with Ren® HY 5160 (Vantico AG).

Photocurable polymer was UV-curable Dymax Ultra Light-Weld® 3094 adhesive and the curing step was done by the UV-light with the wavelength 300-500 nm.

Thermoplastic polymer was poly(9,9-(ethylhexyl)fluorene).

The conductive particles were mixed in the adhesive by stirring for 30 minutes. The particle fraction was 0.2 vol-% or less.

Mixture was aligned using an AC source. In this example the alignment procedure 1 kHz AC-field (0.6-4 kV/cm, rms value) was employed for >10 minutes for >1 mm electrode spacing and <2 minutes for <1 mm electrode spacing.

The alignment was terminated before the chains reached from electrode to electrode. FIG. 3 shows so obtained electrodes with dendritic surface in the case of thermoplastic polymer.

For thermoset polymer curing was performed immediately afterwards at 100° C. for 6 minutes. For photocurable polymer, curing was performed using UV light. For thermoplastic polymer, the system was stabilized by lowering the temperature below melting point and glass transition.

### Example 2

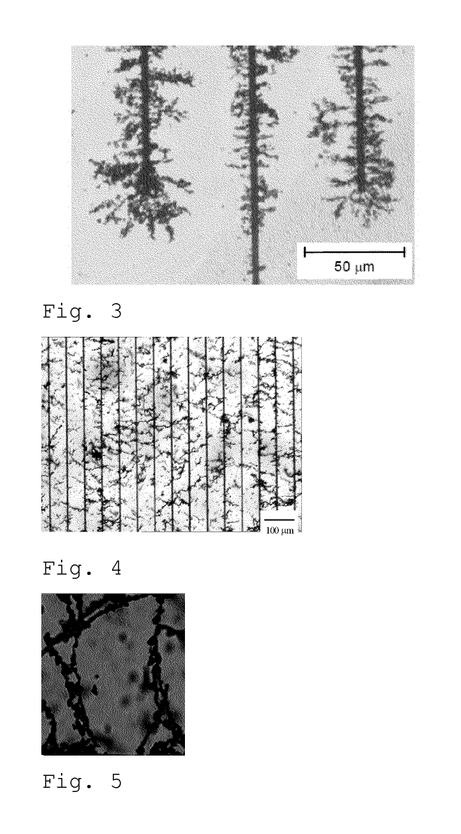

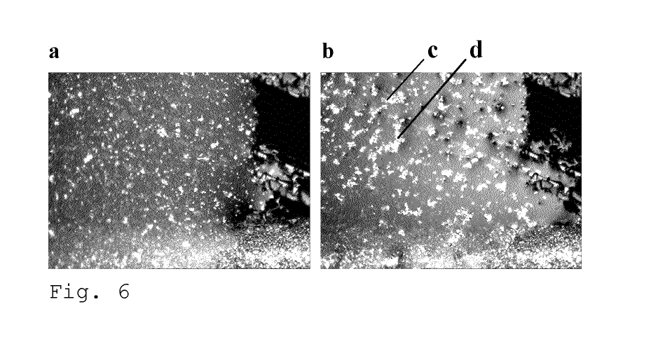

This example is similar to example 1 but instead of using carbon particles iron oxide (Fe₃O₄) or silver flakes were employed. Particle size was in both cases less than 5 microns. Both were purchased from Sigma-Aldrich. Conductivity of formed chains is ˜1 S/m so higher than that of carbon. FIG. 4 and FIG. 5 illustrate the results.

### Example 3

This example is similar to example 2 but here the dendtritic electrodes act as solar cell surface electrodes. FIG. 2 illustrates the idea. FIG. 6 shows micrographs of the surface before, a, and after, b, alignment showing surface of the line like electrodes, c, and the silver dendrimers connected to those, d. The silver mix was 0.75 vol-%. The voltage over the electrode spacing was 1.5 V/cm.

### Example 4

This example is similar to the examples 1-3 but the aligned structures of particles are formed in the particles on the solar cell body using external alignment electrodes.

### Example 5

This example is similar to the examples 1-3 but the aligned structures of particles are formed on an external body and then transferred onto the solar cell body.

1. A method for forming a solar cell having a top electrode comprising a finger pattern, wherein at least part of the finger pattern is formed of a structure of aligned particles, said method comprising
applying a thin film comprising a fluid matrix with conductive particles on to the solar cell surface;
aligning the conductive particles into electrically conductive wires by applying an electric field over the thin film; and
curing the matrix

2. A method in accordance with claim 1, wherein the conductive particles are at least one of a metal, a metal alloy and a metal oxide.

3. A method in accordance with claim 1, wherein the conductive particles are or carbon particles.

4. A method in accordance with claim 1, wherein the aligned conductive particles form thin wires having a width of less than 50 microns or less than 10 microns.

5. A method in accordance with claim 4, wherein the aligned conductive particles form finger lines.

6. A method in accordance with claim 5, further comprising applying a second thin film to the surface and aligning the conductive particles of the second thin film so that a dendrite structure is formed on the finger lines.

7. A method in accordance with claim 1, wherein the thin film is applied to the solar cell surface after finger lines have been printed onto the surface and the conductive particles are aligned so that a dendrite structure is formed on the finger lines.

8. A method in accordance with claim 1, further comprising separately preparing the thin film and transferring the thin film onto the solar cell after alignment of particles.

9. A solar cell manufactured in accordance with claim 1.

10. A silicon solar cell manufactured in accordance with claim 1.

11. The method in accordance with claim 2, wherein the conductive particles are selected from the group consisting of Ag, an alloy of Ag, Cu, Au, Fe, Ti, Fe₃O₄, TiO₂ and mixtures thereof.

12. The method in accordance with claim 3, wherein the carbon particles are selected from the group consisting of carbon nanotubes, carbon nanocones, graphitic particles, graphene particles, carbon black particles and mixtures thereof.
